(19) United States
(12) Patent Application Publication
(10) Pub. No.: US 2025/0374518 A1
(43) Pub. Date: Dec. 4, 2025

(54) MANAGING DISHING RECESS IN SEMICONDUCTOR DEVICES

(71) Applicant: Yangtze Memory Technologies Co., Ltd., Wuhan (CN)

(72) Inventors: Ya WANG, Wuhan (CN); Pengfei ZHANG, Wuhan (CN); Mingliang XU, Wuhan (CN); Yugang WU, Wuhan (CN); Xiuhuan ZOU, Wuhan (CN); Yifeng CHEN, Wuhan (CN)

(21) Appl. No.: 18/790,142

(22) Filed: Jul. 31, 2024

(30) Foreign Application Priority Data
Jun. 4, 2024 (CN) 202410718596.2

(51) Int. Cl. H10B 12/00; H01L 21/764

(52) U.S. Cl. CPC H10B 12/315; H01L 21/764; H10B 12/0335

(57) ABSTRACT

Systems, devices, and methods for managing dishing recess in a semiconductor device are provided. In one aspect, a semiconductor device includes a first body structure located in an array region. The first body structure includes a first connection line extending along a first direction. The semiconductor device includes a second body structure located in an edge region adjacent to the array region. The second body structure includes a second connection line extending along the first direction and having a dishing recess. A width of the second connection line along a second direction is greater than a width of the first connection line along the second direction. The second direction is perpendicular to the first direction. The semiconductor device includes a blocking layer inside the dishing recess of the second connection line.

### CROSS-REFERENCE TO RELATED APPLICATIONS

This application claims priority to Chinese Patent Application No. 202410718596.2, filed on Jun. 4, 2024, which is hereby incorporated by reference in its entirety.

### TECHNICAL FIELD

The present disclosure relates to semiconductor devices and fabrication processes for semiconductor devices.

### BACKGROUND

Semiconductor memory devices may be classified into non-volatile memory devices, such as flash memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for managing dishing recess in three-dimensional (3D) semiconductor devices.

One aspect of the present disclosure features a semiconductor device, including a first body structure located in an array region. The first body structure includes a first connection line extending along a first direction. The semiconductor device includes a second body structure located in an edge region adjacent to the array region. The second body structure includes a second connection line extending along the first direction and having a dishing recess. A width of the second connection line along a second direction is greater than a width of the first connection line along the second direction. The second direction is perpendicular to the first direction. The semiconductor device includes a blocking layer inside the dishing recess of the second connection line.

In some implementations, the blocking layer includes silicon oxide.

In some implementations, a thickness of the blocking layer ranges from about 3 nm to about 10 nm.

In some implementations, the semiconductor device includes a spacer layer in contact with the blocking layer and inside the dishing recess of the second connection line.

In some implementations, the spacer layer includes silicon nitride.

In some implementations, the semiconductor device includes a sacrificial layer inside the dishing recess of the second connection line and having a material different from a material of the blocking layer. The spacer layer is between the blocking layer and the sacrificial layer.

In some implementations, the second body structure includes second semiconductor bodies each having a first end and extending along a third direction. The second connection line connects the first end of each second semiconductor body. The third direction is perpendicular to the first direction and the second direction. The first body structure includes first semiconductor bodies each having a first end and extending along the third direction. The first connection line connects the first end of each first semiconductor body. The semiconductor device includes a gate line adjacent to one of the second semiconductor bodies and a corresponding one of the first semiconductor bodies. A height of the gate line along the third direction in the edge region is greater than a height of the gate line along the third direction in the array region.

In some implementations, a difference between the height of the gate line in the edge region and the height of the gate line in the array region ranges from about 30 nm to about 80 nm.

In some implementations, a height of the second connection line is smaller than about 50 nm.

In some implementations, the first connection line includes a silicide material.

In some implementations, the semiconductor device includes a plurality of first body structures. The plurality of first body structures includes the first body structure. The first connection lines of adjacent first body structures of the plurality of first body structures are separated by a region includes an air gap.

Another aspect of the present disclosure features a semiconductor device including: a first body structure located in an array region. The first body structure includes a first connection line extending along a first direction and first semiconductor bodies. The first semiconductor bodies each includes a first end and extends along a second direction. The first connection line connects the first end of each first semiconductor body. The second direction is perpendicular to the first direction. The semiconductor device includes a second body structure located in an edge region adjacent to the array region. The second body structure includes a second connection line extending along the first direction and second semiconductor bodies. The second semiconductor bodies each includes a first end and extends along the second direction. The second connection line connects the first end of each second semiconductor body and having a dishing recess. The semiconductor device includes a blocking layer inside the dishing recess of the second connection line, and a gate line adjacent to one of the second semiconductor bodies and a corresponding one of the first semiconductor bodies. A height of the gate line in the edge region along the second direction is greater than a height of the gate line in the array region along the second direction.

In some implementations, a width of the second connection line along a third direction is greater than a width of the first connection line along the third direction. The third direction is perpendicular to the first direction and the second direction.

In some implementations, the blocking layer includes silicon oxide.

In some implementations, a thickness of the blocking layer ranges from about 3 nm to about 10 nm.

In some implementations, the semiconductor device includes a spacer layer in contact with the blocking layer and inside the dishing recess of the second connection line.

In some implementations, the spacer includes spacer layer includes silicon nitride.

In some implementations, the semiconductor device includes a sacrificial layer inside the dishing recess of the second connection line and having a material different from a material of the blocking layer. The spacer layer is between the blocking layer and the sacrificial layer.

In some implementations, the gate line extends into a pad-out region. The edge region is between the pad-out region and the array region. A height of the gate line in the pad-out region is greater than the height of the gate line in the edge region along the second direction.

In some implementations, the gate line is coupled to a gate line contact in the pad-out region.

Another aspect of the present disclosure features a method including: forming a body structure array including first body structures and a second body structure. The first body structures each includes a first connection line extending along a first direction. The second body structure includes a second connection line extending along the first direction and having a dishing recess. A width of the second connection line along a second direction is greater than a width of the first connection line of at least one of the first body structures along the second direction. The first body structures and the second body structure are separated by a dielectric material along the second direction. The second direction is perpendicular to the first direction. The method includes forming a gate line adjacent to the body structure array; depositing a blocking layer on the body structure array; etching a portion of the dielectric material to form openings between adjacent first body structures of the first body structures; etching a portion of the gate line adjacent to the first body structures; and forming air gaps in the openings between adjacent first connection lines of the first body structures.

In some implementations, the blocking layer includes silicon oxide.

In some implementations, a thickness of the blocking layer ranges from about 3 nm to about 10 nm.

In some implementations, the method includes depositing a spacer layer on the blocking layer. The spacer layer includes silicon nitride.

In some implementations, etching the portion of the dielectric material includes: depositing a hard mark on the blocking layer; and defining a pattern of the hard mark.

In some implementations, forming the air gaps in the openings includes: depositing a spacer layer inside the openings; and depositing a sacrificial layer in contact with the spacer layer inside the openings. The sacrificial layer includes a material different from a material the blocking layer.

In some implementations, the sacrificial layer includes carbon (C) or titanium nitride (TiN).

In some implementations, the method includes depositing a conductive material on the first body structures; and annealing the conductive material, such that the conductive material reacts with a material of the first body structures to form a composite conductive material.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a cross-section view of an example 3D semiconductor device.

FIG. 2A illustrates a cross-section view of an example semiconductor device.

FIG. 2B illustrates a plan view of an example semiconductor device.

FIG. 2C illustrates a 3D view of an example body structure array of an example semiconductor device.

FIG. 2D illustrates a 3D view of a portion of the body structure array of FIG. 2C.

FIGS. 2E and 2F illustrate cross-section views of an example semiconductor device.

FIGS. 3A through 3L illustrate cross-section views and 3D views of an example semiconductor device at various stages of an example fabrication process.

FIG. 4 is a flow diagram of an example process for forming an example semiconductor device.

FIG. 5 illustrates a block diagram of a system.

It is to be understood that the various exemplary implementations shown in the figures are merely illustrative representations and are not necessarily drawn to scale.

### DETAILED DESCRIPTION

In the manufacturing process of semiconductor devices, dishing recesses may be inadvertently formed on structures, e.g., silicon or silicide structure. Subsequently, conductive material can become trapped inside these dishing recesses. The trapped conductive material in the dishing recess may inadvertently create electrical shorts to other conductive structures, e.g., word line (WL) or WL contacts. These unintended electrical connections between the word lines and the structures can lead to reduced device performance, device malfunction or failure, or circuit damage.

Implementations of the present disclosure provide semiconductor devices and methods to form such semiconductor devices. In some implementations, the semiconductor device includes a first body structure located in an array region. The first body structure includes a first connection line extending along a first direction. The semiconductor device includes a second body structure located in an edge region adjacent to the array region. The second body structure includes a second connection line extending along the first direction and having a dishing recess. A width of the second connection line along a second direction is greater than a width of the first connection line along the second direction. The second direction is perpendicular to the first direction. The semiconductor device includes a blocking layer inside the dishing recess of the second connection line.

Implementations of the present disclosure can provide one or more of the following technical advantages and/or benefits. For example, using a blocking layer made of a dielectric material to fill the dishing recess at least partially can mitigate the risk of short circuits between the structures (e.g., the second body structure described below) and the word lines. This configuration can increase the breakdown voltage between the word lines and second body structures. Increased breakdown voltage can offer several benefits, such as enhanced reliability, reduced risk of device malfunction, and improved yield. In addition, the process window for polishing process (e.g., chemical mechanical polishing) and trench etching can be enlarged, which can enhance manufacturing flexibility, facilitate scaling and reduce manufacture cost.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

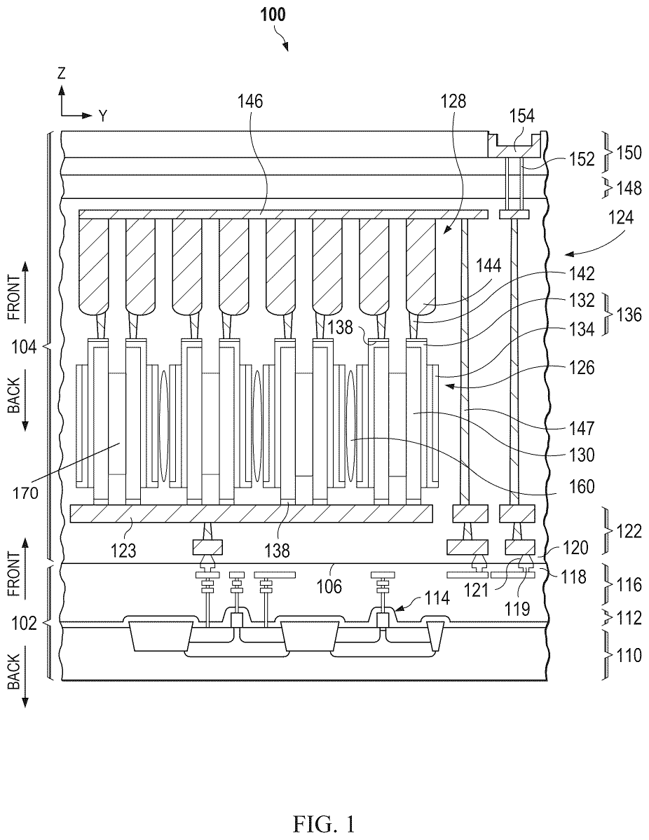

FIG. 1 illustrates a side view of a cross-section of an example 3D semiconductor device 100. The 3D semiconductor device 100 can be a 3D dynamic random-access memory (DRAM). It is understood that FIG. 1 is for illustrative purposes only and may not necessarily reflect the actual device structure (e.g., interconnections) in practice. In some implementations, the 3D semiconductor device 100 is a bonded chip including a first semiconductor structure 102 and a second semiconductor structure 104 stacked over the first semiconductor structure 102. The first and second semiconductor structures 102 and 104 can be jointed at bonding interface 106 therebetween.

As shown in FIG. 1, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on and/or in the substrate 110. In some implementations, the peripheral circuits 112 include a plurality of transistors 114 (e.g., planar transistors and/or 3D transistors). Trench isolations (e.g., shallow trench isolations (STIs)) and doped regions (e.g., wells, sources, and drains of transistors 114) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die 102.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 1, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 1. The dielectric layer can include the bonding interface 106 having the bonding contacts 121. The bit line 123 can also be referred to as the first connection line 123 in this disclosure.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including bit lines 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the bit lines 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact.

In some implementations, the bit line 123 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

In some implementations, the second semiconductor structure 104 includes a DRAM device in which memory cells are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the second semiconductor structure 104 is formed on a semiconductor die and can be referred to as array die 104.

In some implementations, a semiconductor device can include multiple array dies (e.g., the array die 104) and a CMOS die (e.g., the CMOS die 102). The multiple array dies and the CMOS die can be stacked and bonded together. The CMOS die can be respectively coupled to each of the multiple array dies, and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 124 can include a vertical transistor 126 and a capacitor 128 coupled to the vertical transistor 126. DRAM cell 124 can be a 1T1C cell consisting of one transistor and one capacitor. It is understood that DRAM cell 124 may be of any suitable configurations, such as 2T1C cell, 3T1C cell, etc. The vertical transistor 126 can be a MOSFET used to switch a respective DRAM cell 124. In some implementations, the vertical transistor 126 includes a semiconductor body 130 (the active region in which a channel can form) extending vertically (in the z-direction), and a gate structure 136 in contact with one side of semiconductor body 130. In a single-gate vertical transistor, the semiconductor body 130 can have a cuboid shape or a cylinder shape, and the gate structure 136 can abut a single side of semiconductor body 130 in a plane view, e.g., as shown in FIG. 1. In some implementations, the vertical transistor 126 has a structure including two or more gates, e.g., a two-gates structure, a three-gates structure, or a gate all around (GAA) structure. In some implementations, the gate structure 136 includes a gate electrode 134 and a gate dielectric 132 laterally between the gate electrode 134 and the semiconductor body 130 in a bit line direction (e.g., in the Y direction). In some implementations, the gate dielectric 132 abuts one side of the semiconductor body 130, and the gate electrode 134 abuts the gate dielectric 132. The gate electrode 134 can also be referred to as word lines 134 or gate lines 134 in this disclosure.

As shown in FIG. 1, in some implementations, the semiconductor body 130 has two ends (the upper end and lower end in FIG. 1) in the vertical direction (the z-direction), and at least one end (e.g., the lower end) extends beyond gate dielectric 132 in the vertical direction (the z-direction) into the ILD layers. In some implementations, one end (e.g., the upper end) of the semiconductor body 130 is flush with the respective end (e.g., the upper end) of the gate dielectric 132. In some implementations, both ends (the upper end and lower end) of the semiconductor body 130 extend beyond the gate electrode 134, respectively, in the vertical direction (the z-direction) into ILD layers. That is, the semiconductor body 130 can have a larger vertical dimension (e.g., the depth) than that of the gate electrode 134 (e.g., in the z-direction), and neither the upper end nor the lower end of semiconductor body 130 is flush with the respective end of the gate electrode 134. Thus, short circuits between the bit lines 123 and the word lines/gate electrodes 134 or between the word lines/gate electrodes 134 and the capacitors 128 can be avoided. The word lines 134 can also refer to as the gate lines 134 in this disclosure. The vertical transistor 126 can further include a source and a drain (both referred to as 138 as their locations may be interchangeable) disposed at the two ends (the upper end and lower end) of the semiconductor body 130, respectively, in the vertical direction (the z-direction). In some implementations, one of the source and drain 138 (e.g., at the upper end in FIG. 1) is coupled to the capacitor 128, and the other one of source and drain 138 (e.g., at the lower end in FIG. 1) is coupled to the bit line 123. That is, the vertical transistor 126 can have a first terminal in the positive z-direction and a second terminal opposite the first terminal in the negative z-direction, as shown in FIG. 1.

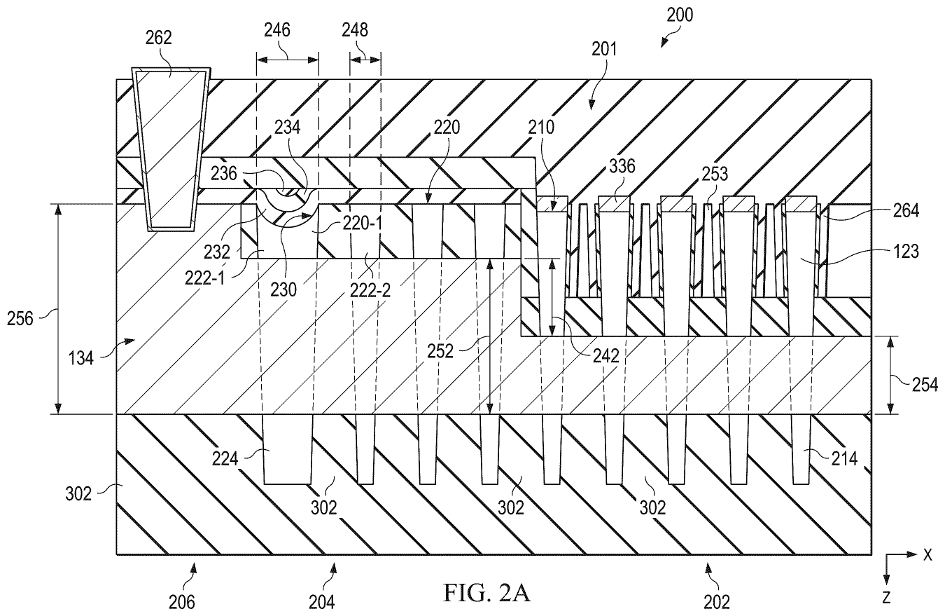

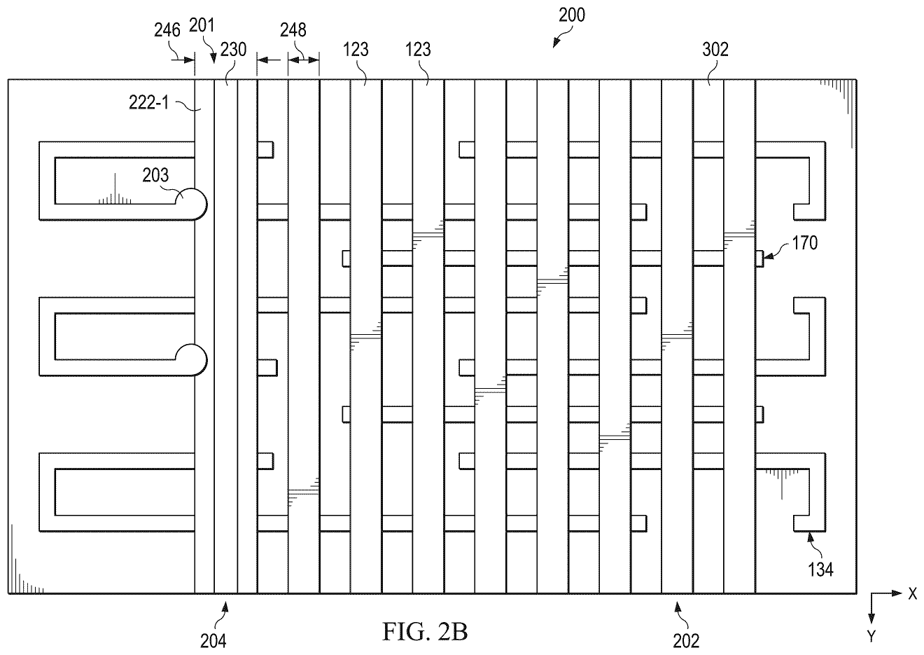

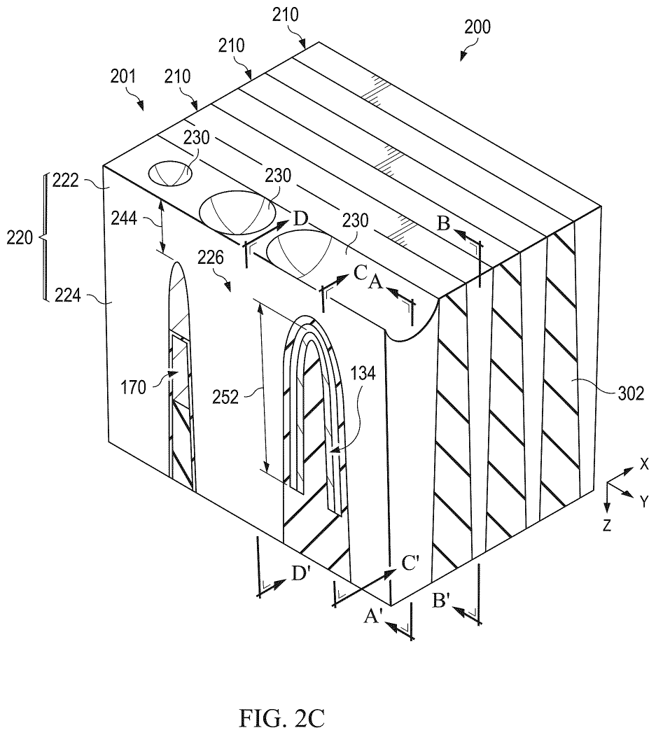

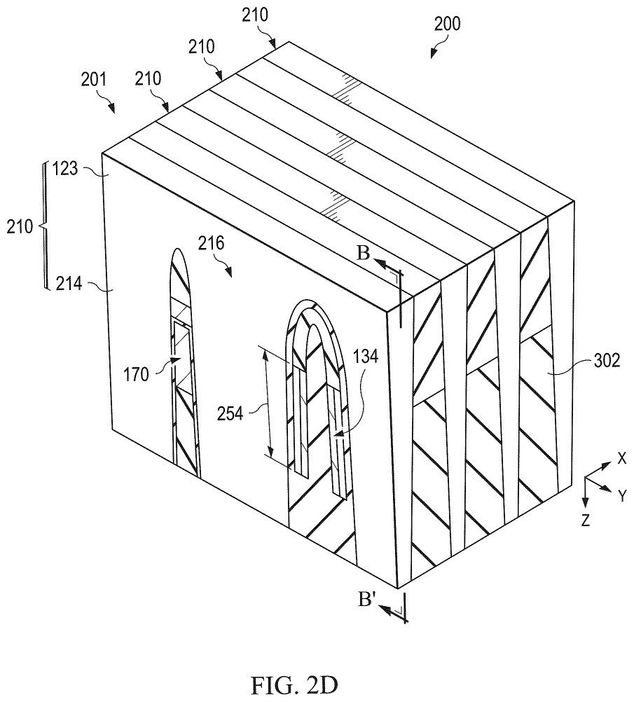

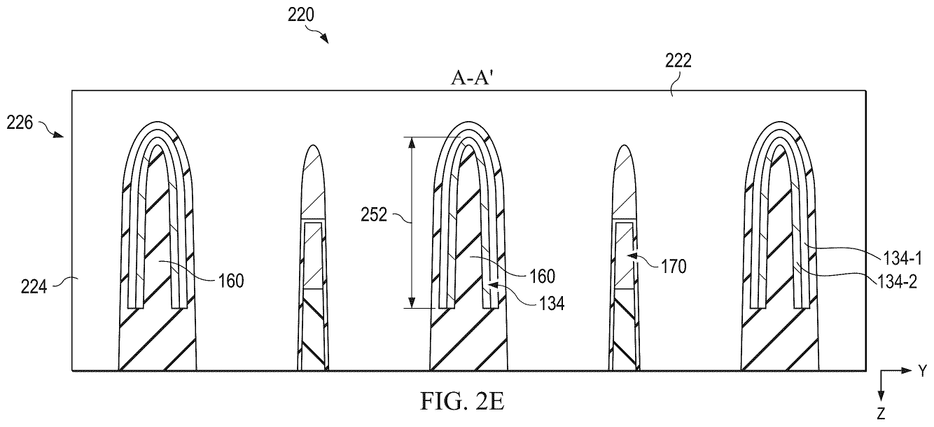

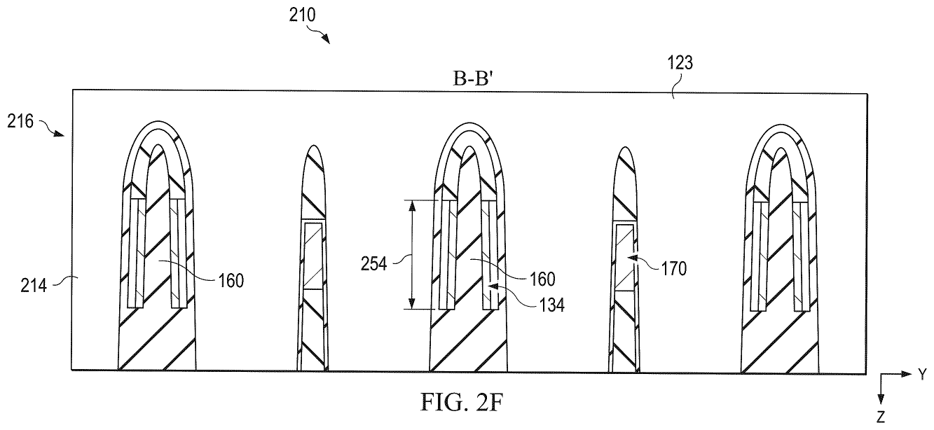

In some implementations, the semiconductor body 130 includes semiconductor materials, such as single crystalline silicon, polysilicon, amorphous silicon, Ge, any other semiconductor materials, or any combinations thereof. In one example, semiconductor body 130 may include single crystalline silicon. Source and drain 138 can be doped with N+ type dopants (e.g., Phosphorus (P) or Arsenic (As)) or P-type dopants (e.g., Boron (B) or Gallium (Ga)) at a desired doping level. In some implementations, a silicide layer, such as a metal silicide layer, is formed between source/drain 138 of the vertical transistor 126 and the bit line 123 as the bit line contact or between source/drain 138 of the vertical transistor 126 and the first electrode of the capacitor 128 as capacitor contact 142 to reduce the contact resistance. In some implementations, gate dielectric 132 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, gate electrode 134 includes a conductive material including, but not limited to W, Co, Cu, Al, TiN, TaN, polysilicon, silicide, or any combination thereof. In some implementations, the gate electrode 134 includes multiple conductive layers, such as a W layer 134-2 over a TiN layer 134-1 (e.g., as illustrated in FIG. 2E). In one example, the gate structure 136 may be a “gate oxide/gate poly” gate in which the gate dielectric 132 includes silicon oxide and gate electrode 134 includes doped polysilicon. In another example, gate structure 136 may be an HKMG in which gate dielectric 132 includes a high-k dielectric and gate electrode 134 includes a metal.

As described above, since the gate electrode 134 may be part of a word line or extend in the word line direction (e.g., the X direction) as a word line, the second semiconductor structure 104 of the 3D semiconductor device 100 can also include a plurality of word lines each extending in the word line direction. Each word line 134 can be coupled to a row of DRAM cells 124. That is, the bit line 123 and the word line 134 can extend in two perpendicular lateral directions, and the semiconductor body 130 of the vertical transistor 126 can extend in the vertical direction perpendicular to the two lateral directions in which the bit line 123 and the word line 134 extend. Word lines 134 are in contact with word line contacts (not shown). In some implementations, the word lines 134 include conductive materials including, but not limited to W, Co, Cu, Al, TiN, TaN, polysilicon, silicides, or any combination thereof. In some implementations, the word line 134 includes multiple conductive layers, such as a W layer over a TiN layer, as shown in FIG. 1.

In some implementations, as shown in FIG. 1, the vertical transistor 126 extends vertically through and contacts the word lines 134, and the source or drain 138 of vertical transistor 126 at the lower end thereof is in contact with the bit line 123 (or bit line contact if any). Accordingly, the word lines 134 and the bit lines 123 can be disposed in different planes in the vertical direction due to the vertical arrangement of vertical transistor 126, which simplifies the routing of the word lines 134 and the bit lines 123. In some implementations, the bit lines 123 are disposed vertically between the bonding layer 120 and the word lines 134, and the word lines 134 are disposed vertically between the bit lines 123 and the capacitors 128. The word lines 134 can be coupled to the peripheral circuits 112 in the first semiconductor structure 102 through word line contacts (not shown) in the interconnect layer 122, the bonding contacts 121 and 119 in the bonding layers 120 and 118, and the interconnects in the interconnect layer 116. Similarly, the bit lines 123 in the interconnect layer 122 can be coupled to the peripheral circuits 112 in the first semiconductor structure 102 through the bonding contacts 121 and 119 in the bonding layers 120 and 118 and the interconnects in the interconnect layer 116.

In some implementations, the vertical transistors 126 can be arranged in a mirror-symmetric manner to increase the density of DRAM cells 124 in the bit line direction (the Y direction). As shown in FIG. 1, two adjacent vertical transistors 126 in the bit line direction are mirror-symmetric to one another with respect to a trench isolation 160. That is, the second semiconductor structure 104 can include a plurality of trench isolations 160 each extending in the word line direction (the X direction) in parallel with word lines 134 and disposed between vertical gates 134 of two adjacent rows of the vertical transistors 126. In some implementations, the rows of vertical transistors 126 separated by the trench isolation 160 are mirror-symmetric to one another with respect to the trench isolation 160. The trench isolation 160 can be formed with dielectric materials including, but not limited to, silicon oxide, silicon nitride, silicon oxynitride, low-k dielectrics, or any combination thereof. It is understood that the trench isolation 160 may include an air gap each disposed laterally between adjacent vertical gates 134. Air gaps may be formed due to the relatively small pitches of vertical transistors 126 in the bit line direction (e.g., the Y direction). On the other hand, the relatively small dielectric constant of air in air gaps (e.g., about ¼ of the dielectric constant of silicon oxide) can improve the insulation effect between vertical transistors 126 (and rows of DRAM cells 124) compared with some dielectrics (e.g., silicon oxide) and reduce parasitic capacitance. Similarly, in some implementations, air gaps are formed laterally between word lines/gate electrodes 134 in the bit line direction as well, depending on the pitches of word lines/gate electrodes 134 in the bit line direction.

In some implementations, instead of the trench isolation 160 having the air gap being disposed between adjacent vertical gates 134 of two adjacent rows of the vertical transistors 126, a shielding conductive structure 170 (e.g., including metal such as W) is disposed between adjacent semiconductor bodies 130 of two adjacent rows of vertical transistors 126. The shielding conductive structure 170 can be in contact with at least one of the adjacent semiconductor bodies 130 and can be coupled to a low voltage (e.g., a fixed negative voltage), which can reduce charge build-up in the memory cells 124, thereby mitigating the floating body effect in the memory cells 124. Moreover, by applying a fixed low voltage on the shielding conductive structure 170 between the memory cells 124, a threshold voltage of the memory cells 124 can be conveniently adjusted, which can reduce the overall manufacturing complexity and cost, and improve reliability of the memory cells 124. Further, the conductive structure 170 can be coupled out from a same side as word lines or a different side from the word lines. For example, the shielding conductive structure 170 can be coupled out from the back side of the second semiconductor structure 104. The shielding conductive structure 170 can be also referred as shielding conductive material. The trench isolation having such shielding conductive structure 170 may be also referred to as trench isolation (TISO) in this disclosure.

As shown in FIG. 1, in some implementations, a capacitor 128 includes a first electrode 144 above and coupled to the source or drain 138 of vertical transistor 126, e.g., the upper end of the semiconductor body 130, via a capacitor contact 142. In some implementations, the capacitor contact 142 is an ohmic contact, such as a metal silicide contact, as opposed to a Schottky contact. For example, the capacitor contact 142 may include metal silicides, such as WSi, CoSi, CuSi, AlSi, or any other suitable metal silicides having higher conductivities than doped silicon. The capacitor 128 can also include a capacitor dielectric above and in contact with the first electrode 144, and a second electrode above and in contact with the capacitor dielectric. That is, the capacitor 128 can be a vertical capacitor in which the electrodes and capacitor dielectric are stacked vertically (in the z-direction), and the capacitor dielectric can be sandwiched between the electrodes. In some implementations, each first electrode is coupled to source or drain 138 of a respective vertical transistor 126 in the same DRAM cell, while all second electrodes are coupled to a common plate 146 coupled to the ground, e.g., a common ground. The capacitor 128 can have a first end in the negative z-direction and a second end opposite the first end in the positive z-direction, as shown in FIG. 1. In some implementations, the first end of the capacitor 128 is coupled to the first terminal of the vertical transistor 126 via an ohmic contact (e.g., the capacitor contact 142 made of a metal silicide material). As shown in FIG. 1, the second semiconductor structure 104 can further include a capacitor contact 147 (e.g., a conductor) in contact with a common plate 146 for coupling the capacitors 128 to the peripheral circuits 112 or to the ground directly. In some implementations, the capacitor contact 147 (e.g., a conductor) extends in the z-direction from the dielectric layer of the bonding layer 120 to couple to the second end of the capacitor 128 via the common plate 146, as shown in FIG. 1. In some implementation, the ILD layer in which the capacitors 128 are formed has the same dielectric material as the two ILD layers into which the semiconductor body 130 extends, such as silicon oxide.

It is understood that the structure and configuration of a capacitor 128 are not limited to the example in FIG. 1 and may include any suitable structure and configuration, such as a planar capacitor, a stack capacitor, a multi-fins capacitor, a cylinder capacitor, a trench capacitor, or a substrate-plate capacitor. In some implementations, the capacitor dielectric includes dielectric materials, such as silicon oxide, silicon nitride, or high-k dielectrics including, but not limited to, Al₂O₃, HfO₂, Ta₂O₅, ZrO₂, TiO₂, or any combination thereof. It is understood that in some examples, a capacitor 128 may be a ferroelectric capacitor used in a FRAM cell, and the capacitor dielectric may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 1, vertical transistor 126 extends vertically through and contacts the word lines 134, source or drain 138 of vertical transistor 126 at the lower end thereof is in contact with the bit line 123, and source or drain 138 of vertical transistor 126 at the upper end thereof is coupled to the capacitor 128. That is, the bit line 123 and the capacitor 128 can be disposed in different planes in the vertical direction and coupled to opposite ends of vertical transistor 126 of DRAM cell 124 in the vertical direction due to the vertical arrangement of vertical transistor 126. In some implementations, the bit line 123 and the capacitor 128 are disposed on opposite sides of the vertical transistor 126 in the vertical direction, which simplifies the routing of the bit lines 123 and reduces the coupling capacitance between the bit lines 123 and the capacitors 128 compared with DRAM cells in which the bit lines and capacitors are disposed on the same side of the planar transistors.

As shown in FIG. 1, in some implementations, the vertical transistors 126 are disposed vertically between the capacitors 128 and the bonding interface 106. That is, the vertical transistors 126 can be arranged closer to the peripheral circuits 112 of the first semiconductor structure 102 and the bonding interface 106 than the capacitors 128. Since the bit lines 123 and the capacitors 128 are coupled to opposite ends of the vertical transistors 126, the bit lines 123 (as part of the interconnect layer 122) are disposed vertically between the vertical transistors 126 and the bonding interface 106 As a result, the interconnect layer 122 including bit lines 123 can be arranged close to the bonding interface 106 to reduce the interconnect routing distance and complexity.

In some implementations, the second semiconductor structure 104 further includes a substrate 148 disposed above the DRAM cells 124. The substrate 148 can be part of a carrier wafer. It is understood that in some examples, the substrate 148 may not be included in the second semiconductor structure 104.

As shown in FIG. 1, the second semiconductor structure 104 can further include a pad-out interconnect layer 150 above the substrate 148 and the DRAM cells 124. The pad-out interconnect layer 150 can include interconnects, e.g., contact pads 154, in one or more ILD layers. The pad-out interconnect layer 150 and the interconnect layer 122 can be formed on opposite sides of the DRAM cells 124. The capacitors 128 can be disposed vertically between the vertical transistors 126 and the pad-out interconnect layer 150. In some implementations, the interconnects in pad-out interconnect layer 150 can transfer electrical signals between the 3D semiconductor device 100 and outside circuits, e.g., for pad-out purposes.

In some implementations, the second semiconductor structure 104 further includes one or more contacts 152 extending through the substrate 148 and part of the pad-out interconnect layer 150 to couple the pad-out interconnect layer 150 to the DRAM cells 124 and the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contacts 152 and pad-out interconnect layer 150. Contact pads 154 and contacts 152 can include conductive materials including, but not limited to, W, Co, Cu, Al, silicides, or any combination thereof. In one example, the contact pad 154 may include Al, and the contact 152 may include W. In some implementations, the contact 152 includes a via surrounded by a dielectric spacer (e.g., having silicon oxide) to electrically separate the via from substrate 148. Depending on the thickness of substrate 148, contact 152 can be an ILV having a depth in the submicron level (e.g., between 10 nm and 1 μm), or a TSV having a depth in the micron- or tens micron-level (e.g., between 1 μm and 100 μm).

Although not shown, it is understood that the pad-out of 3D memory devices is not limited to from the second semiconductor structure 104 having DRAM cells 124 as shown in FIG. 1 and may be from the first semiconductor structure 102 having peripheral circuit 112. Although not shown, it is also understood that the air gaps between word lines 134 and/or between semiconductor bodies 130 may be partially or fully filled with dielectrics. Although not shown, it is further understood that more than one array of DRAM cells 124 may be stacked over one another to vertically scale up the number of DRAM cells 124.

In some implementations, instead of having the substrate 148 above the DRAM cells 124 as shown in FIG. 1, the second semiconductor structure 104 includes a substrate disposed below the DRAM cells 124. The substrate can be part of a carrier wafer. The DRAM cells 124 can be formed in a front side of the substrate, and the bit lines 123 can be formed in a back side of the substrate. The bit lines 123 can be conductively coupled to the DRAM cells 124 (e.g., the terminals 138 of the vertical transistors 126) through the substrate.

FIGS. 2A-2F illustrates schematic views of an example semiconductor device 200. The semiconductor device 200 can be implemented as the semiconductor device 100 or a part of the semiconductor device 100 depicted in FIG. 1. FIG. 2A illustrates a cross-section view of the semiconductor device 200 in X-Z plane. FIG. 2B illustrate a plan view of the semiconductor device 200 in X-Y plane. FIG. 2C illustrates a 3D view of a body structure array of the semiconductor device 200. FIG. 2D illustrates a 3D view of a portion of the body structure array of FIG. 2C with the first body structures. FIGS. 2E-2F illustrate cross-section views of the semiconductor device 200 in Y-Z plane, similar to views through A-A′ and B-B′ axis of FIGS. 2C-2D. X-direction can be the word line direction. Y-direction can be the bit line direction. Z-direction can be the direction that is perpendicular to the substrate surface (e.g., the substrate 110 or the substrate 148 of FIG. 1). The three directions are perpendicular to each other.

It is to be understood that FIG. 2A can be a composite view with overlays of various cross-section planes that are parallel to the X-Z plane. For example, FIG. 2A can be a composite view of cross-section planes similar to those through C-C′ axis and D-D′ axis of FIG. 2C, such that FIG. 2A can illustrate both the gate line and the semiconductor bodies in a single view. Therefore, FIG. 2A is for illustrative purpose only and may not depict a single cross-sectional view within an actual device. It is further to be understood that FIGS. 2A-2F can be a flipped view of the part of the semiconductor device 100 in FIG. 1 along Z direction. For ease of description, reference will be made to all figures when describing the structure of the semiconductor device 200.

Referring to FIG. 2A, the semiconductor device 200 includes a body structure array 201. The body structure array 201 includes at least one first body structure 210 and at least one second body structure 220. The at least one first body structures 210 can be in the array region 202. The at least one second body structure 220 can be in the edge region 204. Adjacent first body structures 210 and adjacent second body structures 220 are separated from one another by a dielectric material 302. The array region 202 can be the region where active memory cells 124 are formed. The edge region 204 can be the region that is at the edge of the array region 202 and includes dummy structures, e.g., without active memory cells 124. The edge region 204 can be between the array region 202 and a pad-out region 206. The pad-out region 206 can be the region for padding out gate lines for the memory cells 124.

Referring to FIGS. 2D and 2F, the first body structure 210 includes a first connection line 123 extending along a first direction, e.g., Y-direction or bit line direction. The first connection line 123 can be implemented as the bit line 123 as depicted in FIG. 1. Multiple first connection lines 123 are arranged along the word line direction, e.g., the X direction (FIG. 2B). In some implementations, the first connection line 123 is made of a conductive material including, but not limited to W, Co, Cu, Al, TiN, TaN, polysilicon, or any combination thereof. In some implementations, the first connection line 123 is made of a composite conductive material that can be based on a metallic material (e.g., Ni, W, Co, Cu, Al) and a semiconductor material (e.g., Si). For example, the composite conductive material can include metal silicide, e.g., such as NiSi, WSi, CoSi, CuSi, AlSi, or any other suitable metal silicides having higher conductivities than doped silicon.

In some implementations, the first body structure 210 includes first semiconductor bodies 214 (FIGS. 2D and 2F). The first semiconductor body 214 has a first end 216 and extends along the third direction, e.g., Z direction. The first connection line 123 connects the first ends 216 of corresponding first semiconductor bodies 214. The first semiconductor bodies 214 can be implemented as the semiconductor body 130 depicted in FIG. 1. In some implementations, the first body structure 210 has a comb shape (FIGS. 2C and 2F).

The semiconductor device 200 includes a second body structure 220 located in the edge region 204 adjacent to the array region 202. Referring to FIGS. 2C and 2E, the second body structure 220 includes a second connection line 222 extending along the first direction, e.g., the bit line direction. In some implementations, the second body structure 220 includes second semiconductor bodies 224 extending along a third direction, e.g., Z direction. Each of the second semiconductor bodies 224 has a first end 226. The second connection line 222 connects the first ends 226 of corresponding second semiconductor bodies. In some implementations, the second connection line 222 has identical or substantially similar material to that of the first connection line 123, and the second semiconductor bodies 224 have identical or substantially similar material to that of the first semiconductor bodies 214. In some implementations, the second body structure 220 has a comb shape.

Referring to FIGS. 2A-2B, a width 246 of at least one of the second connection lines 222 along a second direction, e.g., the word line direction (X direction), is greater than a width 248 of at least one of the first connection line 123 along the same direction. In some implementations, the second body structure 220 has identical or substantially similar height (e.g., along Z direction) and length (e.g., along Y direction) to those of the first body structure 210. The body structure array 201 can include two or more second body structures 220. In some implementations, only the second connection line 222-1 of the outermost second body structure 220, e.g., the second body structure 220-1, is wider than at least one of the first connection lines 123. Other second connection line 222, e.g., the second connection line 222-2, can have identical or substantially similar width to that of the first connection line 123.

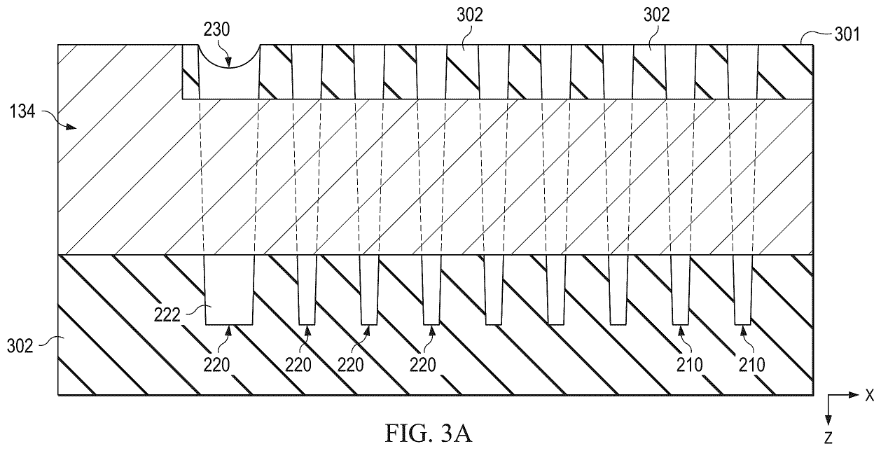

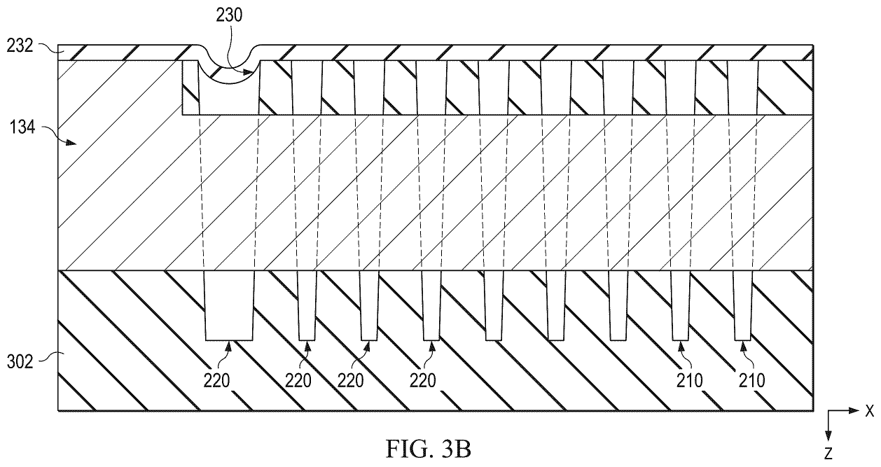

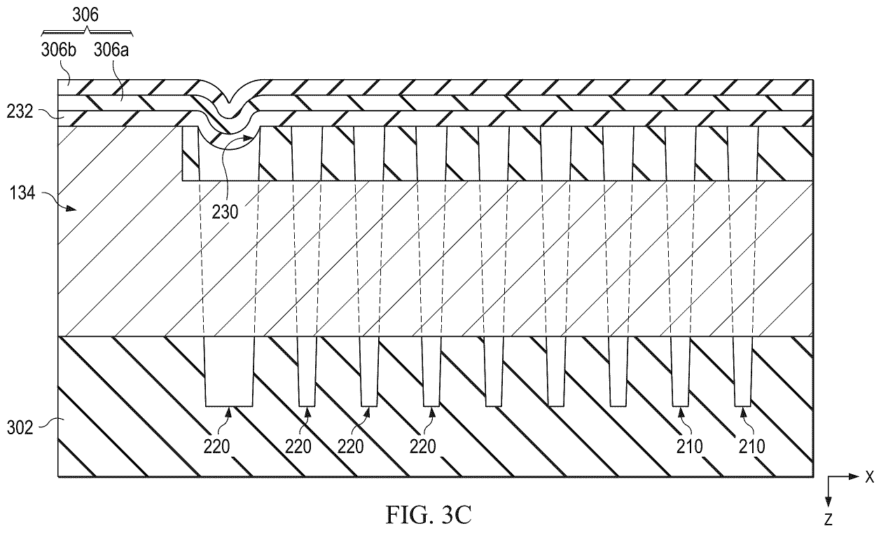

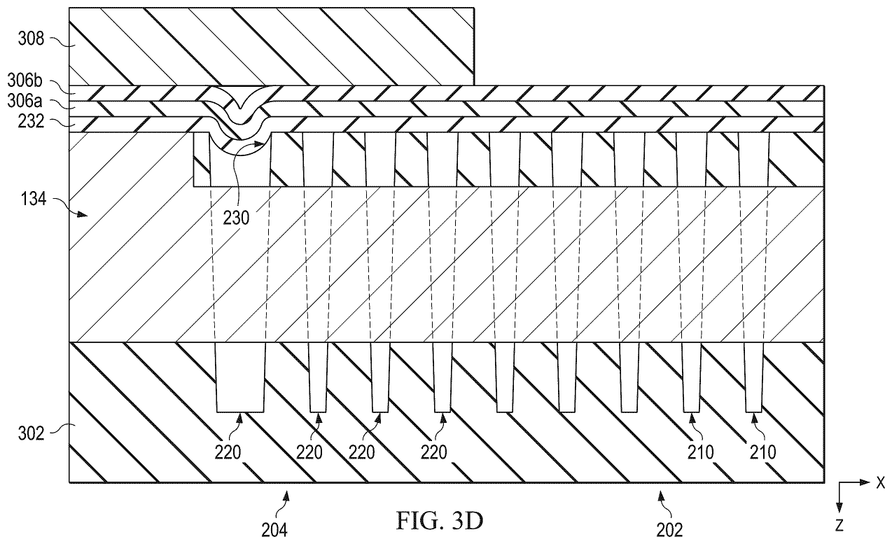

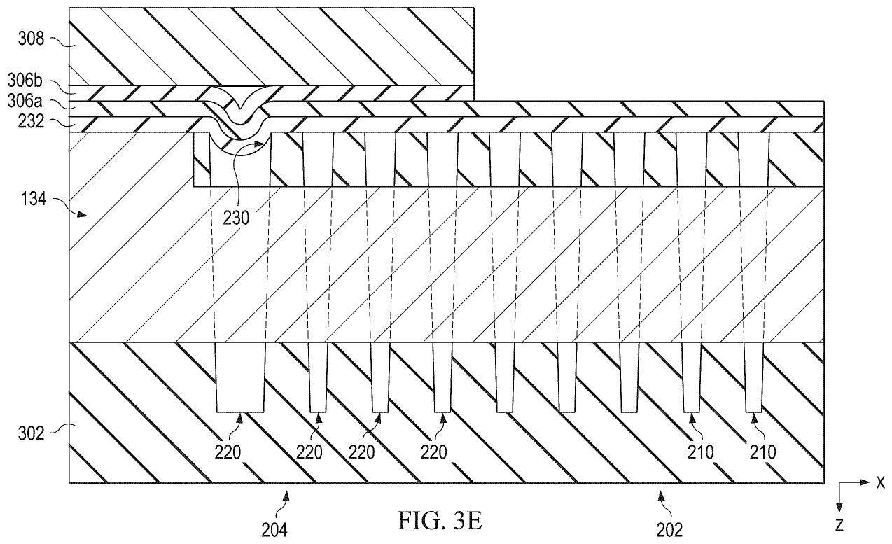

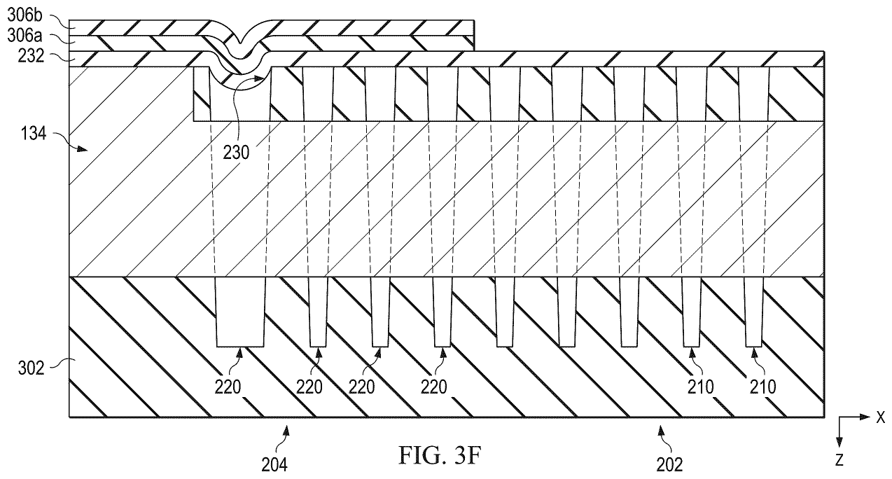

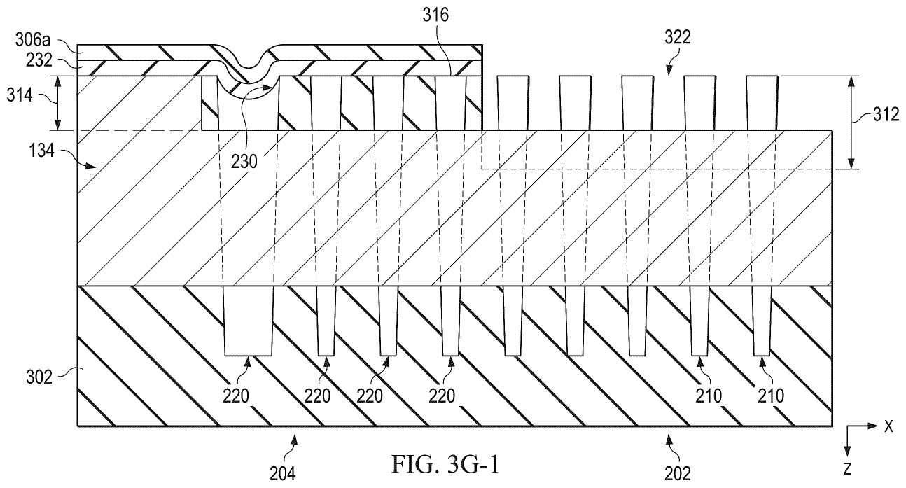

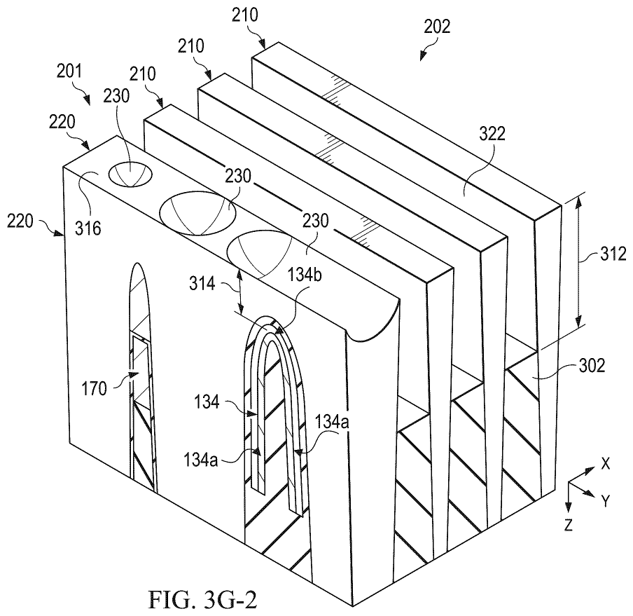

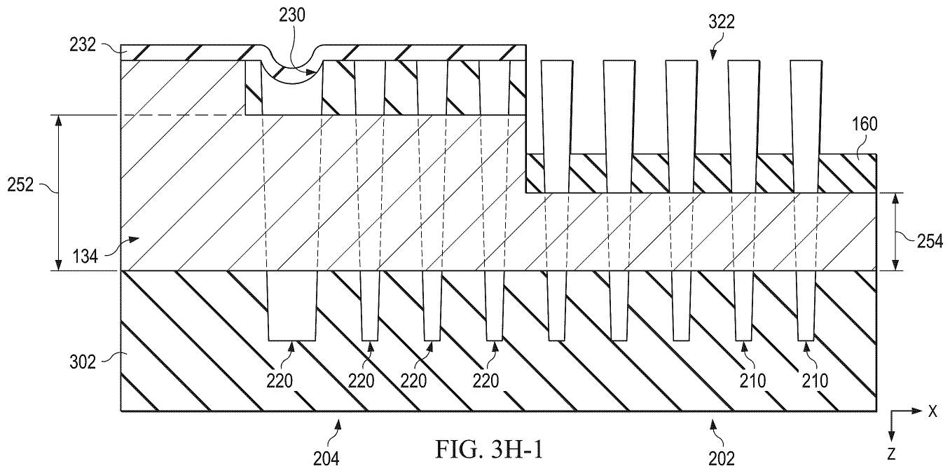

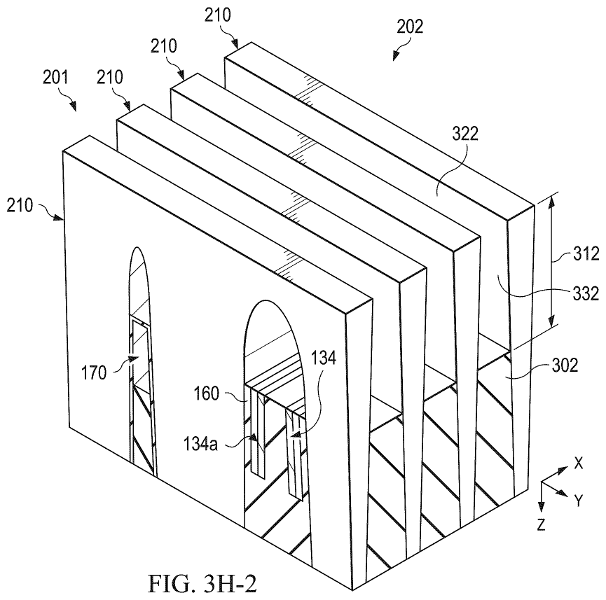

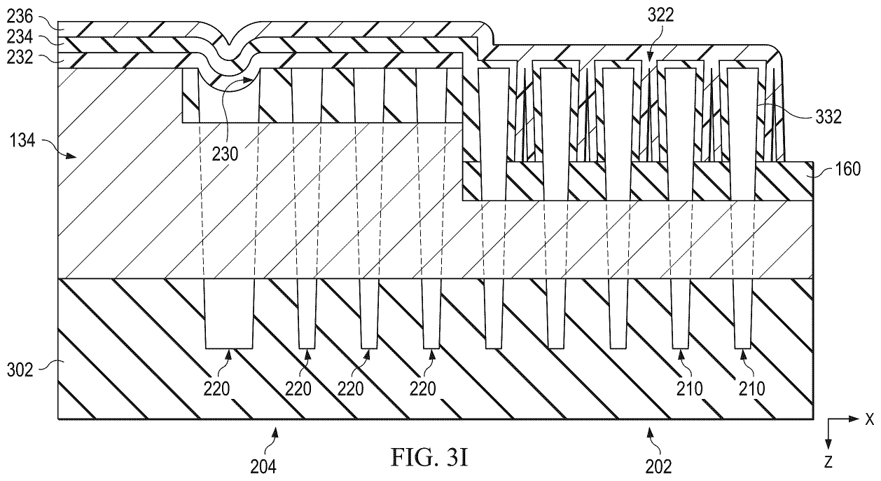

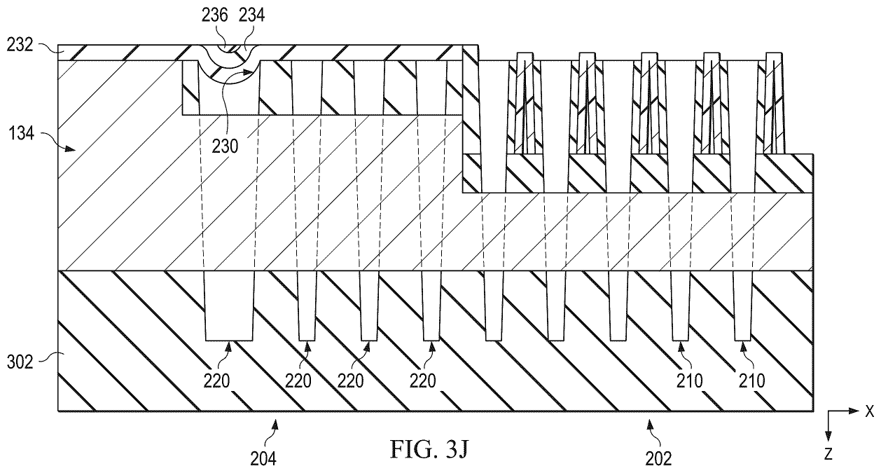

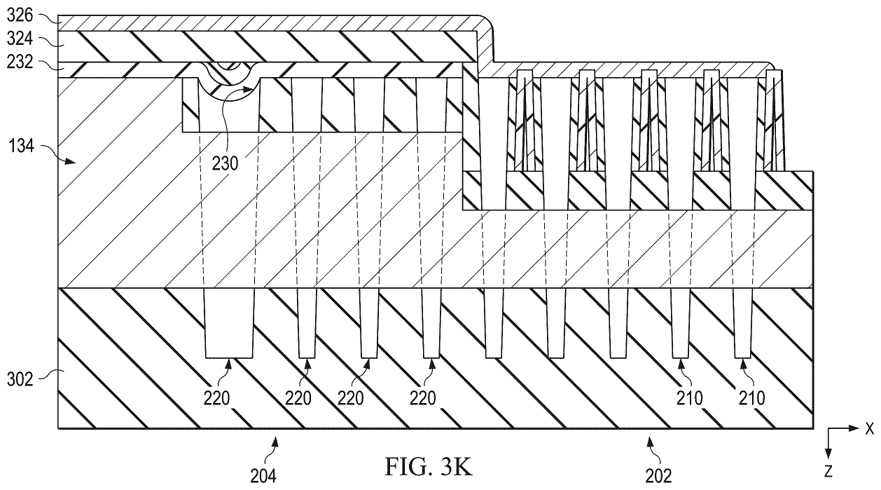

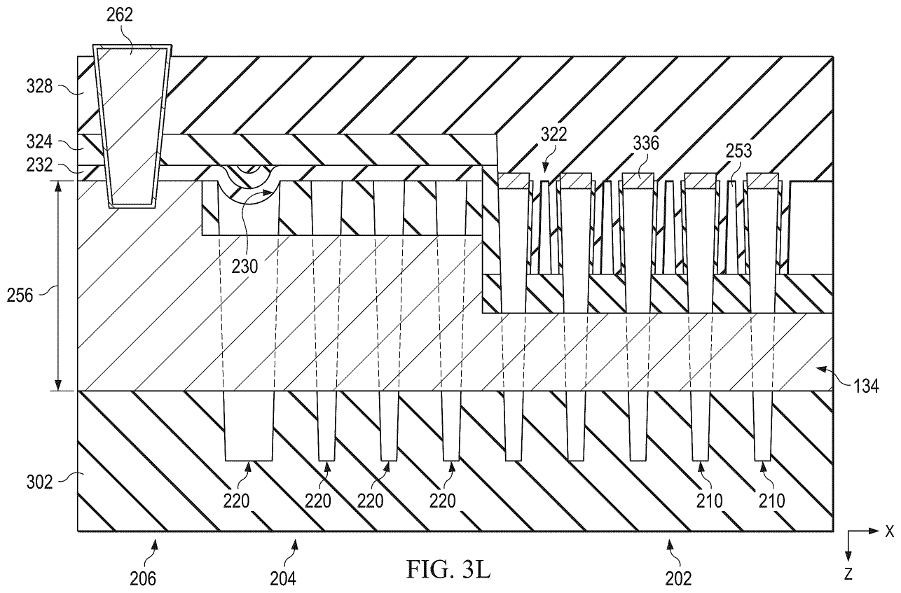

Referring to FIGS. 2A-2C, the second connection line 222 has a dishing recess 230. The dishing recess 230 can be a cavity with a concave shape, which is formed during semiconductor fabrication process, e.g., thinning or polishing process. As the second connection line 222 of the second body structure 220 can have a larger critical dimension (CD) (e.g., width along X-direction), the thinning process (e.g., chemical-mechanical polishing (CMP)) may cause dishing recess 230, e.g., due to slurry selectivity ratio. The dishing recess 230 can have various shapes. In some implementations, the dishing recess 230 has an elongated shape along the bit line direction (e.g., the Y-direction) (FIG. 2B). In some implementations, the dishing recess 230 has a pit shape (FIG. 2C). In some implementations, multiple dishing recess 230 with varying shapes are formed on a single second connection line 222 (FIG. 2C). It is to be understood that as dishing recess 230 can be inadvertently formed during semiconductor fabrication processes, the shape and dimension of the dishing recess 230 can vary depending on factors such as the CMP process parameters, the properties of the substrate material, and/or the specific pattern being polished. It is further to be understood that the shapes and dimensions of the dishing recess 230 depicted in FIGS. 2A-3L is for illustration purpose and is not intended to be construed in a limiting sense.

As noted above, in some situations, a conductive material may be trapped inside the dishing recess 230. As noted above, although the dishing recess 230 depicted in FIG. 2B has an elongated shape, it is not intended to be construed in a limiting sense. The dishing recess 230 can exhibit any shapes or dimensions. Because the second body structure 220 is adjacent to the pad-out region 206 for padding out gate lines 134, the dishing recess 230 may be shorted (not shown) to the gate line 134 or gate line contacts 262 due to their close proximity. In some situations, referring to FIG. 2B, conductive defects 203 may be present, which further increases the risk of short circuits. This unintended electrical connections between the gate lines 134 and the second body structures 220 can lead to reduced device performance, device malfunction or failure, or circuit damage. It is to be understood that the defects 203 is for illustrative purpose only. In an actual device, defects 203 may not be present.

To address this issue, as illustrated in FIG. 2A, the semiconductor device 200 includes a blocking layer 232 to at least partially fill the dishing recess 230. The blocking layer 232 can be made of a dielectric material including, but not limited to, silicon oxide, silicon nitride, silicon oxynitride, or any combination thereof. By partially filling the dishing recess 230 with dielectric materials, there can be less space available to trap conductive materials, thereby reducing the risk of short circuits. The process for forming the blocking layer 232 inside the dishing recess 230 are described with further details below in the descriptions of FIGS. 3A-3L.

In some implementations, the blocking layer 232 includes silicon oxide. In some implementations, a thickness of the blocking layer 232, e.g., along Z direction, ranges from about 3 nm to about 10 nm. As illustrated in FIG. 2A, in some implementations, the semiconductor device 200 further includes a spacer layer 234 in contact with the blocking layer 232 and inside the dishing recess 230 of the second connection line 222. In some implementations, the spacer layer 234 includes silicon nitride. In some implementations, the semiconductor device 200 further includes a sacrificial layer 236 inside the dishing recess 230 of the second connection line 222. The spacer layer 234 is between the blocking layer 232 and the sacrificial layer 236. The sacrificial layer 236 can have a material different from a material of the blocking layer 232. In some implementations, the sacrificial layer 236 includes a conductive material, including, but not limited to W, Co, Cu, Al, TiN, TaN, polysilicon, or any combination thereof. In some implementations, the sacrificial layer 236 is made of a material including silicon carbide (SiC), or any other suitable materials exhibiting etch selectivity with silicon nitride or silicon oxide. In some implementations, the blocking layer 232 includes silicon oxide, the spacer layer 234 includes silicon nitride, and the sacrificial layer 236 includes TiN or SiC.

In some implementations, the semiconductor device 200 further includes the gate line 134 adjacent to one of the second semiconductor bodies 224 and a corresponding one of the first semiconductor bodies 214. In some implementations, referring to FIGS. 2A and 2C-2F, a height 252 of the gate line 134 along the third direction, e.g., the Z direction, in the edge region 204 is greater than a height 254 of the gate line 134 along the same direction in the array region 202. In some implementations, a difference 242 (FIG. 2A) between the height 252 of the gate line 134 in the edge region 204 and the height 254 of the gate line 134 in the array region 202 ranges from about 30 nm to about 80 nm. In some implementations, a height 244 (FIG. 2C) of the second connection line 222 is smaller than about 50 nm.

Referring to FIG. 2A, in some implementations, the gate line 134 extends into the pad-out region 206. A height 256 of the gate line 134 in the pad-out region 206 is greater than the height 252 of the gate line 134 in the edge region 204 along the Z direction. In some implementations, the gate line 134 is coupled to a gate line contact 262 in the pad-out region 206. In some implementations, the gate line 134 and/or the gate line contact 262 are made of a conductive material including, but not limited to W, Co, Cu, Al, TiN, TaN, polysilicon, silicide, or any combination thereof. In some implementations, the gate line 134 and/or the gate line contact 262 includes multiple conductive layers, such as a W layer over a TiN layer.

In some implementations, the semiconductor device 200 includes a plurality of first body structures 210. Referring to FIG. 2A, the first connection lines 123 of adjacent first body structures 210 can be separated by a region including an air gap 253 and a dielectric material 264. Air gaps 253 can be formed due to the relatively small pitches of adjacent first connection lines 123 in the bit line direction (e.g., the Y direction). On the other hand, the relatively small dielectric constant of air in air gaps (e.g., about ¼ of the dielectric constant of silicon oxide) can improve the insulation effect between the first connection lines 123 compared with some dielectrics (e.g., silicon oxide) and reduce parasitic capacitance between adjacent first connection lines 123.

FIGS. 3A-3L illustrate cross-section views and 3D views of the semiconductor device 200 at various stages of an example fabrication process. It is to be understood that cross-section views of FIGS. 3A-3L can be composite views with overlays of various cross-section planes that are parallel to the X-Z plane, similar to FIG. 2A.

As illustrated in FIG. 3A, a polishing process can be performed to polish the top part 301 of the semiconductor device 200. As noted above, the second connection line 222 may have the dishing recess 230 due to its greater width along the word line direction, e.g., X direction. The polishing process can include mechanical thinning (e.g., grinding, polishing, and/or chemical mechanical polishing (CMP)), chemical thinning (e.g., wet etching, dry etching), laser thinning, acoustic thinning, or any combination thereof.

As illustrated in FIG. 3B, a blocking layer 232 can be deposited. The blocking layer 232 can include dielectric materials including, but not limited to, silicon oxide, silicon nitride, silicon oxynitride, or any combination thereof. In some implementations, the blocking layer 232 includes silicon oxide. In some implementations, a thickness of the blocking layer 232, e.g., along Z direction, ranges from about 3 nm to about 10 nm. The blocking layer 232 can be deposited using one or more thin film deposition techniques, including, but not limited to, chemical vapor deposition (CVD), physical vapor deposition (PVD), atomic layer deposition (ALD), sputtering, or any combination thereof.

As illustrated in FIG. 3C, hard mask (HM) 306 can be deposited on top of the blocking layer 232. In some implementations, the hard mask 306 includes two layers, e.g., a conductive layer 306a and a dielectric HM layer 306b. The conductive layer 306a can include TiN. The dielectric HM layer 306b can include silicon oxide, silicon nitride, silicon oxynitride, or any combination thereof. The dielectric HM layer 306b can be deposited using chemical vapor deposition (CVD), physical vapor deposition (PVD), atomic layer deposition (ALD), sputtering, or any combination thereof. The conductive layer 306a can be deposited by one or more thin film deposition processes including, but not limited to, CVD, PVD, ALD, Metal-Organic Chemical Vapor Deposition (MOCVD), sputtering, electroplating, electroless plating, electron-beam evaporation, or any combination thereof.

As illustrated in FIG. 3D, a patterned photoresist layer 308 can be formed on the hard mask 306. The patterned photoresist layer 308 can be used to transfer the pattern onto the hard mask 306 during subsequent etching process. The patterned photoresist layer 308 can either be positive or negative, depending on whether they become soluble or insoluble when exposed to light. The patterned photoresist layer 308 can cover the dishing recess 230 in the edge region 204. In some implementations, the patterned photoresist layer 308 defines the array region 202 and the edge region 204. For example, the region covered by the patterned photoresist layer 308 can be the edge region 204, while the uncovered region can be the array region 202.

As illustrated in FIG. 3E, the dielectric HM layer 306b of the hard mask 306 can be partially etched. The remaining portion of the dielectric HM layer 306b can have identical or substantially similar pattern to that of the patterned photoresist layer 308. The etch can be selective etching such that the etchants only remove the dielectric HM layer 306b or have a higher etch rate for the dielectric HM layer 306b than for the conductive layer 306a. The etching process can involve one or more dry etching and/or wet etching techniques, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof.

As illustrated in FIG. 3F, the conductive layer 306a of the hard mask 306 can be partially etched. The remaining portion of the conductive layer 306a can have the same or substantially similar pattern to that of the patterned photoresist layer 308 or the patterned dielectric HM layer 306b. The patterned photoresist layer 308 can be also removed at this process stage. The etching process can involve one or more dry etching and/or wet etching techniques described above.

FIGS. 3G-1 and 3G-2 illustrates a cross-sectional view and a 3D view at the same or similar process stage. For illustrative purpose, only one second body structure 220 is shown in FIG. 3G-2. It is to be understood that the semiconductor device 200 can include two or more second body structures 220 as shown in FIG. 3G-1.

As illustrated in FIG. 3G-1, the dielectric HM layer 306b can be removed, exposing the conductive layer 306a of the hard mask 306. In addition, the dielectric materials 302 (FIG. 3A) between adjacent first body structures 210 can also be partially recessed, forming bit line (BL) trenches 322 between them. The gate lines 134 at this process stage can have a U-shape, as illustrated in FIG. 3G-2. The gate lines 134 can include two vertical gate line segments 134a extending along Z direction, and one connection segment 134b extending along Y-direction which can have a curved shape connecting the two vertical gate line segments 134a. In some implementations, the recess height 312 of the dielectric material 302 is greater than a distance 314 between the top surface 316 of the second connection line 222 and the connection segment 134b of the gate lines 134, as illustrated in FIGS. 3G-1 and 3G-2. The etching or recess process can involve one or more dry etching and/or wet etching techniques described above.

FIGS. 3H-1 and 3H-2 illustrates a cross-sectional view and a 3D view at the same or similar process stage. It is to be understood that for illustrative purpose, FIG. 3H-2 only depicts the array region 202 with four first body structures 210 without the inclusion of any second body structures 220.

As illustrated in FIG. 3H-1, the conductive layer 306a of the hard mask 306 can be removed, exposing the blocking layer 232. In addition, a portion of the gate lines 134 in the array region 202 can also be removed. The gate lines 134 in the edge region 204 can remain unetched. Therefore, a height 252 of the gate line 134 along the third direction, e.g., the Z direction, in the edge region 204 is greater than a height 254 of the gate line 134 in the array region 202. As illustrated in FIG. 3H-2, during etch the connection segment 134b of the gate lines 134 can be removed in the array region 202, leaving two vertical gate line segments 134a unconnected to each other. Therefore, each vertical gate line segment 134a can independently drive the corresponding transistors 126 it is connected to. Although FIG. 3H-2 shows that the dielectric structure in the trench isolation 160 is also partially removed, it is to be understood that, in some implementations, the dielectric structures in the trench isolation 160 can largely remain intact, with only the portion of the gate lines 134 being removed, as shown in FIGS. 2F and 3H-1.

In some implementations, in the edge region 204, the connection segment 134b of the gate lines 134 is unetched. Therefore, in the edge region 204, the two vertical gate line segments 134a can be still connected through the connection segment 134b, as illustrated in FIGS. 2E and 3G-2. As noted above, the edge region 204 can be a dummy structure region without active memory cells 124. Although the gate lines 134 can be connected to corresponding transistors 126 in the edge region 204, these transistors 126 may not be used as active memory cells 124 for storing data.

As illustrated in FIG. 3I, the spacer layer 234 can be deposited. The spacer layer 234 can at least partially fill the dishing recess 230 and cover sidewalls 332 of the BL trenches 322. In some implementations, the sacrificial layer 236 is deposited on top of the spacer layer 234. The sacrificial layer 236 can also at least partially fill the dishing recess 230 and the BL trenches 322. The spacer layer 234 can be used to protect the sidewalls 332 of the first body structure 210 as well as the exposed gate lines 134 (FIG. 3H-2) from subsequent acid etchants. As noted above, FIG. 3I can be a composite view of overlays of multiple cross-section planes, and thus it doesn't show that the spacer layer 234 is directly in contact with the gate lines 134. It is understood that in an actual device the spacer layer 234 can be in contact with the gate lines 134 in the array region 202. The spacer layer 234 can safeguard the gate lines 134 from being removed. The sacrificial layer 236 can be used to at least partially fill the BL trenches 322 between adjacent first body structures 210, as a subsequent polishing process (FIG. 3J) may require a filled surface. In some implementations, the spacer layer 234 is made of a material, including without limitation to, silicon oxide, silicon nitride, silicon oxynitride, or any combination thereof. The sacrificial layer 236 can have a material different from a material of the blocking layer 232. In some implementations, the sacrificial layer 236 includes a conductive material, including, but not limited to W, Co, Cu, Al, TiN, TaN, polysilicon, or any combination thereof. In some implementations, the sacrificial layer 236 is made of a material including silicon carbide (SiC). In some implementations, the blocking layer 232 includes silicon oxide, the spacer layer 234 includes silicon nitride, and the sacrificial layer 236 includes TiN or silicon carbide.

As illustrated in FIG. 3J, a polishing process can be performed to remove at least part of the sacrificial layer 236 and the spacer layer 234. Although FIG. 3J illustrates that all three layers (e.g., the blocking layer 232, the spacer layer 234 and the sacrificial layer 236) remain inside the dishing recess 230 after polishing, it is to be understood that, in some implementations, the spacer layer 234 and/or the sacrificial layer 236 is not present in the dishing recess 230. The polishing process can include mechanical thinning (e.g., grinding, polishing, and/or chemical mechanical polishing (CMP)), chemical thinning (e.g., wet etching, dry etching), laser thinning, acoustic thinning, or any combination thereof.

As illustrated in FIG. 3K, another dielectric layer 324 can be formed in the edge region 204. The dielectric layer 324 can be made of a material including, without limitation to, silicon oxide, silicon nitride, silicon oxynitride, or any combination thereof. A conductive layer 326 can be deposited to form a silicide layer 336 at a later stage (FIG. 3L) of the process. The conductive layer 326 can be made of a material including without limitation to Ni, W, Co, Cu, Al, or any combination thereof.

As illustrated in FIG. 3L, which is identical or substantially similar to FIG. 2A, the silicide layer 336 can be formed on the first body structures 210 by performing a silicidation process. The silicidation process can involve an annealing process. During annealing, the deposited conductive layer 326 can react with the silicon in the first connection lines 123 of the first body structures 210 to form a composite conductive material, e.g., the silicide layer 336. In some implementations, the silicide layer 336 includes without limitation to NiSi, WSi, CoSi, CuSi, AlSi, or any other suitable metal silicides. The portion of the conductive layer 326 that has not undergone silicidation can be subsequently removed, e.g., by acid etchants, leaving only the silicide layer 336 on top of the first connection lines 123.

In some implementations, the sacrificial layer 236 is removed from the BL trenches 322, forming air gaps 253 within the BL trenches 322. The removal process for the un-silicidated portion of the conductive layer 326 and/or the sacrificial layer 236 can involve one or more dry etching and/or wet etching techniques, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof. The removal process can also involve CMP. In some implementations, additional dielectric layer 328 is deposited. The dielectric layer 328 can have identical or substantially similar material to that of the dielectric layer 324.

As noted above, the gate line 134 in the pad-out region 206 can have a greater height 256 than that in the edge region 204 and the array region 202. Without being bound to any particular theory, during gate trench etching, lower silicon density can lead to deeper gate trenches formation in the pad-out region 206 compared to those in the edge region 204 and the array region 202. The gate lines 134 can be formed by depositing conductive materials, e.g., a W layer over a TiN layer, into the gate trenches. Therefore, the gate lines 134 can have a greater height 256 in the pad-out region 206. In some implementations, the gate line contact 262 is formed in the pad-out region 206, which connects to a corresponding gate line 134. The formation of gate line contact 262 can involve a plurality of processes including, but not limited to, photolithography, dry/wet etch, thin film deposition, thermal growth, chemical mechanical polishing (CMP), and any other suitable processes. The gate line contact 262 can include multiple conductive layers, such as a W structure surrounded by a TiN layer.

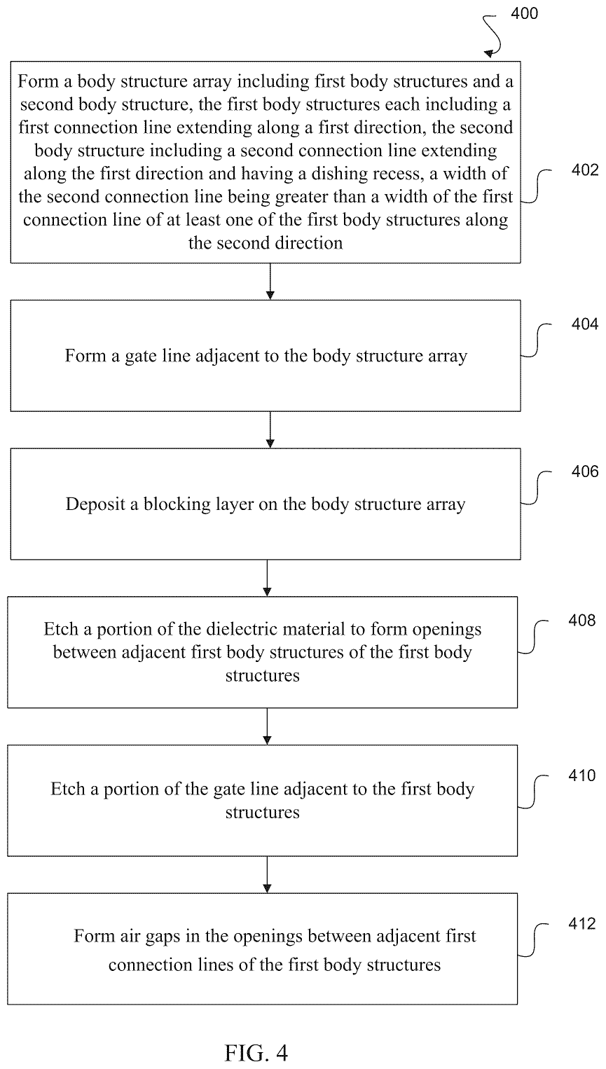

FIG. 4 is a flow diagram of an example process 400 for forming the example semiconductor device 200. At step 402, a body structure array is formed. The body structure includes first body structures and a second body structure. The first body structures each includes a first connection line extending along a first direction. The second body structure includes a second connection line extending along the first direction and having a dishing recess. A width of the second connection line along a second direction is greater than a width of the first connection line of at least one of the first body structures along the second direction. The first body structures and the second body structure are separated by a dielectric material along the second direction. The second direction is perpendicular to the first direction. The body structure can be, e.g., any one of the body structure array 201 of FIGS. 2A-2D and 3A-3L. The first body structures can be, e.g., any one of the first body structure 210 of FIGS. 2A-2D, 2F and 3A-3L. The second body structure can be, e.g., any one of the second body structure 220 of FIGS. 2A-2E and 3A-3L. The first connection line can be, e.g., the first connection line 123 of FIGS. 1-2D, 2F and 3A-3L. The second connection line can be, e.g., the second connection line 222 of FIGS. 2A-2E and 3A-3L. The width of the second connection line can be, e.g., the width 246 of the second connection line 222 of FIGS. 2A-2B. The width of the first connection line can be, e.g., the width 248 of the first connection line 123 of FIGS. 2A-2B. The dielectric material can be, e.g., the dielectric material 302 of FIGS. 2A-3L. The first direction can be, e.g., the Y-direction or the bit line direction. The second direction can be, e.g., the Z-direction or the word line direction.

At step 404, a gate line is formed adjacent to the body structure array. The gate line can be, e.g., the gate line 134 of FIGS. 1-3L.

At step 406, a blocking layer is deposited on the body structure array. The blocking layer can be, e.g., the blocking layer 232 of FIGS. 2A and 3B-3L.

At step 408, a portion of the dielectric material is etched to form openings between adjacent first body structures of the first body structures. The openings can be, e.g., the BL trenches 322 of FIGS. 3G-1 through 3L.

At step 410, a portion of the gate line adjacent to the first body structures is etched.

At step 412, air gaps are formed in the openings between adjacent first connection lines of the first body structures. The air gaps can be, e.g., the air gaps 253 of FIGS. 2A and 3L.

In some implementations, the blocking layer includes silicon oxide. In some implementations, a thickness of the blocking layer ranges from 3 nm to 10 nm.

In some implementations, the process 400 includes depositing a spacer layer on the blocking layer. The spacer layer includes silicon nitride. The spacer layer can be, e.g., the spacer layer 234 of FIGS. 2A and 3I-3L.

In some implementations, etching the portion of the dielectric material includes: (i) depositing a hard mark on the blocking layer; and (ii) defining a pattern of the hard mark. The hard mask can be, e.g., the hard mask 306 of FIGS. 3C through 3G-1.

In some implementations, forming the air gaps in the openings includes: (i) depositing a spacer layer inside the openings; and (ii) depositing a sacrificial layer in contact with the spacer layer inside the openings. The sacrificial layer includes a material different from a material the blocking layer. The sacrificial layer can be, e.g., the sacrificial layer 236 of FIGS. 2A and 3I-3L. In some implementations, the sacrificial layer includes carbon (C) or titanium nitride (TiN).

In some implementations, the process 400 includes depositing a conductive material on the first body structures; and annealing the conductive material, such that the conductive material reacts with a material of the first body structures to form a composite conductive material. The conductive material can be, e.g., the conductive layer 326 of FIG. 3K. The composite conductive material can be, e.g., the silicide layer 336 of FIGS. 2A and 3L.

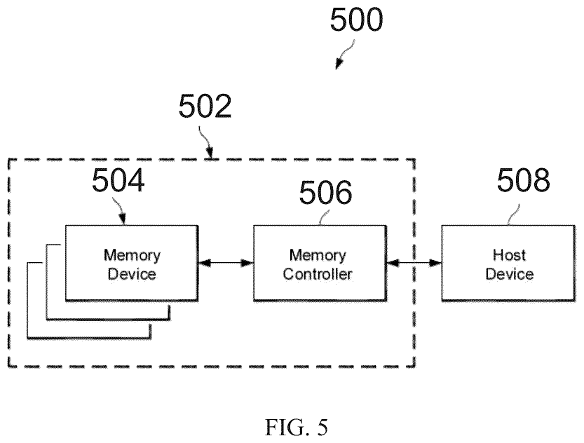

FIG. 5 illustrates a block diagram of a system 500 having one or more semiconductor device 200s (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 5, the system 500 can include a host device 608 and a memory system 602 having one or more 3D memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more 3D memory devices 504.

A 3D memory device 504 can be any 3D memory device disclosed herein, such as the 3D semiconductor device 100 of FIG. 1, or the 3D semiconductor device 200 of FIGS. 2A-2F, or a structure at an intermediate fabrication process of the 3D semiconductor device 200 of FIGS. 3A-3L.

In some implementations, a 3D memory device 504 includes a NAND Flash memory. Memory controller 506 (a.k.a., a controller circuit) is coupled to 3D memory device 504 and host device 508. Consistent with implementations of the present disclosure, 3D memory device 504 can include a plurality of conductive interconnections through a cover layer that are in contact with conductive pads in a conductive pad layer, and memory controller 506 can be coupled to 3D memory device 504 through at least one of the plurality of conductive interconnections. Memory controller 506 is configured to control 3D memory device 504. For example, memory controller 506 may be configured to operate a plurality of channel structures via gate lines 134. Memory controller 506 can manage data stored in 3D memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of 3D memory device 504, such as read, erase, and program (or write) operations. Memory controller 506 can also be configured to manage various functions with respect to the data stored or to be stored in 3D memory device 504 including, but not limited to bad-block management, garbage collection, logical-to-physical address conversion, wear leveling, etc. In some implementations, memory controller 506 is further configured to process error correction codes (ECCs) with respect to the data read from or written to 3D memory device 504. Any other suitable functions may be performed by memory controller 506 as well, for example, formatting 3D memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more 3D memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a single 3D memory device 504 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” “one implementation,” “an implementation,” “an example implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric HM layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., +−0.10%, +−0.20%, or +−0.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first body structure located in an array region, the first body structure comprising a first connection line extending along a first direction;
a second body structure located in an edge region adjacent to the array region, wherein the second body structure comprises a second connection line extending along the first direction and having a dishing recess, a width of the second connection line along a second direction being greater than a width of the first connection line along the second direction, the second direction being perpendicular to the first direction; and
a blocking layer inside the dishing recess of the second connection line.

2. The semiconductor device of claim 1, wherein the blocking layer comprises silicon oxide.

3. The semiconductor device of claim 1, wherein a thickness of the blocking layer ranges from about 3 nm to about 10 nm.

4. The semiconductor device of claim 1, further comprising a spacer layer in contact with the blocking layer and inside the dishing recess of the second connection line.

5. The semiconductor device of claim 4, wherein the spacer layer comprises silicon nitride.

6. The semiconductor device of claim 5, further comprising a sacrificial layer inside the dishing recess of the second connection line and having a material different from a material of the blocking layer, wherein the spacer layer is between the blocking layer and the sacrificial layer.

7. The semiconductor device of claim 1,
wherein the second body structure comprises second semiconductor bodies each having a first end and extending along a third direction, the second connection line connecting the first end of each second semiconductor body, the third direction being perpendicular to the first direction and the second direction,
wherein the first body structure comprises first semiconductor bodies each having a first end and extending along the third direction, the first connection line connecting the first end of each first semiconductor body,
wherein the semiconductor device further comprises a gate line adjacent to one of the second semiconductor bodies and a corresponding one of the first semiconductor bodies, and
wherein a height of the gate line along the third direction in the edge region is greater than a height of the gate line along the third direction in the array region.

8. The semiconductor device of claim 7, wherein a difference between the height of the gate line in the edge region and the height of the gate line in the array region ranges from about 30 nm to about 80 nm.

9. The semiconductor device of claim 1, wherein a height of the second connection line is smaller than about 50 nm.

10. A semiconductor device, comprising:
a first body structure located in an array region, wherein the first body structure comprises a first connection line extending along a first direction and first semiconductor bodies, the first semiconductor bodies each comprising a first end and extending along a second direction, the first connection line connecting the first end of each first semiconductor body, the second direction being perpendicular to the first direction;
a second body structure located in an edge region adjacent to the array region, wherein the second body structure comprises a second connection line extending along the first direction and second semiconductor bodies, the second semiconductor bodies each comprising a first end and extending along the second direction, the second connection line connecting the first end of each second semiconductor body and having a dishing recess;
a blocking layer inside the dishing recess of the second connection line; and
a gate line adjacent to one of the second semiconductor bodies and a corresponding one of the first semiconductor bodies, a height of the gate line in the edge region along the second direction being greater than a height of the gate line in the array region along the second direction.

11. The semiconductor device of claim 10, wherein a width of the second connection line along a third direction is greater than a width of the first connection line along the third direction, the third direction being perpendicular to the first direction and the second direction.

12. The semiconductor device of claim 10, wherein the blocking layer comprises silicon oxide.

13. The semiconductor device of claim 10, wherein a thickness of the blocking layer ranges from about 3 nm to about 10 nm.

14. The semiconductor device of claim 10, further comprising a spacer layer in contact with the blocking layer and inside the dishing recess of the second connection line.

15. The semiconductor device of claim 14, further comprising a sacrificial layer inside the dishing recess of the second connection line and having a material different from a material of the blocking layer, wherein the spacer layer is between the blocking layer and the sacrificial layer.

16. A method, comprising:
forming a body structure array comprising first body structures and a second body structure, the first body structures each comprising a first connection line extending along a first direction, the second body structure comprising a second connection line extending along the first direction and having a dishing recess, a width of the second connection line along a second direction being greater than a width of the first connection line of at least one of the first body structures along the second direction, the first body structures and the second body structure being separated by a dielectric material along the second direction, the second direction being perpendicular to the first direction;
forming a gate line adjacent to the body structure array;
depositing a blocking layer on the body structure array;
etching a portion of the dielectric material to form openings between adjacent first body structures of the first body structures;
etching a portion of the gate line adjacent to the first body structures; and
forming air gaps in the openings between adjacent first connection lines of the first body structures.

17. The method of claim 16, wherein the blocking layer comprises silicon oxide.

18. The method of claim 16, wherein a thickness of the blocking layer ranges from about 3 nm to about 10 nm.

19. The method of claim 16, further comprising: depositing a spacer layer on the blocking layer, wherein the spacer layer comprises silicon nitride.

20. The method of claim 16, wherein forming the air gaps in the openings comprises:
depositing a spacer layer inside the openings; and
depositing a sacrificial layer in contact with the spacer layer inside the openings, the sacrificial layer comprising a material different from a material the blocking layer.
